(19) United States
(12) Patent Application Publication
(10) Pub. No.: US 2009/0026534 A1
(43) Pub. Date: Jan. 29, 2009

(54) Trench MOSFET and method of making the same

(75) Inventors: Tsung-Chih Yeh, Jhongpu Township (TW); Kou-Liang Jaw, Hsinchu (TW); Teck-Wei Chen, Banciao City (TW)

Correspondence Address: BIRCH STEWART KOLASCH & BIRCH, PO BOX 747, FALLS CHURCH, VA, 22040-0747, US

(73) Assignee: MOSEL VITELIC INC.

(21) Appl. No.: 12/010,972

(22) Filed: Jan. 31, 2008

(30) Foreign Application Priority Data
Feb. 2, 2007 (TW) 96103942

(51) Int. Cl. H01L 21/336; H01L 29/78

(52) U.S. Cl. 257/330; 438/270; 257/E21.41; 257/E29.262

(57) ABSTRACT

A trench MOSFET structure formed in a semiconductor substrate and method of forming the same are disclosed. The trench MOSFET includes a capacitor having a capacitor dielectric layer formed of an oxide-un-doped poly-oxide in the trench bottom. Firstly, the trenches are formed in a p-well of the epi-layer of an n-type impurity doped substrate through a lithographic and an etch step. Next, a gate oxide layer and an intrinsic polysilicon layer are successively formed, and a HTO layer is deposited on the trench bottom to form the oxide-un-doped poly-oxide dielectric layer. Subsequently a doped polysilicon layer is filled into the trench as a trench gate. Then, processes of source contact regions and gate contacts are followed. Finally a drain contact is formed on a rear surface of the substrate.

### BACKGROUND OF THE INVENTION

(1) Field of the Invention

The present invention relates to a trench MOSFET formed in a semiconductor substrate, specifically, to a method of having an oxide-undoped poly-oxide as a stacked dielectric layer into the trench bottom for reducing the gate to drain capacitance.

(2) Description of the Prior Art

With the advance of integrated circuits technology into the ultra large-scale integrated circuit (ULSI) era, the design trend of devices is to reduce the sizes thereof in order to approach aims of high integration density, low operation voltage and current consumption. Consequently, more critical and complicated processes including of low resistance tolerance are required.

In present technology, a bipolar transistor is replaced gradually with a Metal-Oxide-Semiconductor Field-Effect Transistor (MOSFET). Because of having advantages of power saving and faster switch speed, the MOSFET is the most useful semiconductor device in present IC field. In general, the principal operation of the trench power MOSET is similar to the MOSFET, but the current of the former can be several order of magnitude amperes higher than the latter.

According to aforementioned, a Trench power MOSET has been used to provide high current and low power consuming characteristics in operating the device. An exemplary method to form the Trench power MOSET is shown in FIG. 1a to FIG. 1d. Referring to FIG. 1a, a substrate 100 is prepared as a drain electrode firstly and an epi-layer 101 is then formed thereon. Afterward, an ion implant is performing to form a body region 105 into the epi-layer 101 and a number of trenches 102 are formed therein.

Referring to FIG. 1b, a gate oxide layer 104 is formed on the sidewall of the trench 102 and then a poly-silicon layer 106 is filled into the trench 102. After removing the gate oxide layer 104 and portion of the poly-silicon layer 106 through an etching process, the surface of the substrate 100 is exposed. The poly-silicon layer 106 remained in the bottom of the trench 102 is used as a gate electrode.

Referring to FIG. 1c, the body region 105 is patterned to define a source electrode. Thereafter, a thermal oxidation is then performed to drive the impurities in the substrate to form source electrode 108. Finally, a dielectric layer 110 and a metal layer 112 are deposited on the aforementioned surface, as shown in FIG. 1d.

With the development of the tiny device, the thinner gate oxide layer is demanded in manufacturing the trench power MOSET. Thus, such a conventional trench power MOSET, however, has a terrible problem of having an increase of gate to drain capacitance at high switching rate and resulting in RC time delay.

Therefore, an object of the present method is provided to overcome above problem and improve the performance of the trench power MOSET.

### SUMMARY OF THE INVENTION

An object of the present invention is to provide a method of forming a bottom dielectric layer in the trench on the substrate.

Another object of the present invention is to introduce a method of using an oxide-undoped poly-oxide dielectric layer for reducing the gate to drain capacitance.

The present invention discloses a method of forming a bottom dielectric layer in the trench. For a start, a thermal oxide layer is formed by thermal oxidation on an epi layer, which is formed on an n-type impurity doped substrate, and to defined an active region and trenches through a lithographic and an etch step. Afterward, a gate oxide layer is formed on bottoms and sidewalls of the trenches and extended to a mesa surface of the epi-layer. Furthermore, an intrinsic polysilicon layer is deposited along the surface of the gate oxide layer through chemical vapor deposition (CVD), and then a high temperature oxide layer (HTO) layer is formed on the intrinsic polysilicon layer by the same approach. After stripping the HTO layer formed on the trench sidewall, a silicon nitride layer (SiN) is deposited along the HTO layer by low pressure chemical vapor deposition (LPCVD) and then a photoresist layer is deposited on entire surfaces and filled into the trenches at the same time. The photoresist layer is then patterned to form a mask using the lithographic step so as to protect the HTO layer inside the trench and to expose the SiN layer on the surface of the epi-layer. After removing the exposed SiN layer, the HTO layer, remaining photoresist pattern and the SiN layer that is protected by said remaining photoresist pattern are successively removed. Finally, an oxide-undoped poly-oxide dielectric layer is formed in the trench bottom. A polycrystalline silicon layer is subsequently doped through an in-situ doped process on the surface of the epi-layer and filled into the trenches. And then the doped polysilicon layer and the intrinsic polysilicon layer located on the surface besides the opening of the trench are removed through an etching back process for exposing the gate oxide layer. A first photoresist pattern is then formed on the aforementioned surface to define positions of source regions. Thereafter, a first ion implant is carried out to implant n-type ions into the epi-layer so as to form source regions, using the first photoresist pattern as a mask. After stripping the first photoresist pattern, an inter-layer dielectrics layer is then deposited on the mesa surface of the epi-layer and the doped polysilicon layer by CVD. Subsequently, a patterning process is done to define a source contact region and a gate contact position. Next, a metal layer is also deposited on the inter-layer dielectrics layer pattern through sputtering process. Then a top metal layer is formed to connect the source contact region with the trench gate contact region by using a pattern process. Finally, a metal layer is formed as a drain electrode on the n+ heavily doped layer of the rear surface.

### DESCRIPTION OF THE PREFERRED EMBODIMENTS

The method of forming a Trench MOSFET according to the present invention is disclosed. Please refer to the cross-sectional views from FIG. 2a to FIG. 2l.

Referring to FIG. 2a, an n-type impurity doped substrate 200 having an impurity-doped epi-layer as a drift layer 205 formed thereon is prepared firstly. A p-well 208 is then formed in the epi-layer 205 and extended to the outer surface of the epi-layer by using a lithographic and an ion implant technology. Thereafter, a first oxide layer 210 is formed on the epi-layer 205 through a thermal oxidation process and then defined an active region 215 through a lithographic and an etch step. Next, a second oxide layer 220 deposited on the mesa surface of the epi-layer 205 is followed. A pattern process is then carried out to pattern the second oxide layer so as to form a hard mask 220 having a trench opening pattern 230A.

Turning to FIG. 2b, the epi-layer 205 is etched through anisotropic etch to form pluralities of trenches 230B using the hard mask pattern 220 as an etch mask. According to a preferred embodiment, the trench bottom is lower than the bottom of the p-well 208. The depth of the trench 230B from its bottom to the surface of the epi-layer is about 0.6 μm˜5 μm. After aforementioned steps, a sacrificial oxide layer (not shown) is formed through an oxidation process that is aimed at recovering lattices, which are damaged by etching process.

Please refer to FIG. 2c, after the hard mask 220 and the pad oxide removal, a gate oxide layer 235 is formed on the trench 230B bottom and sidewall, and further, extended to the entire surfaces of the epi-layer 205. The gate oxide layer 235 is a layer formed by thermal deposition or a thermal oxide layer formed by thermal oxidation or a poly-oxide layer by polysilicon deposition and re-oxidation. Preferably, the gate oxide layer 235 is between about 200˜600 Å. Afterward, an intrinsic polycrystalline silicon layer 240 is deposited on the entire surfaces of the gate oxide layer 235 by chemical vapor deposition (CVD) in the meanwhile. According to a preferred embodiment, the thickness of the intrinsic polycrystalline silicon layer 240 is about 300˜800 Å. A HTO layer 245 is then deposited along the surfaces of the intrinsic polycrystalline silicon layer 240 through a thermal deposition process. In general, the thermal oxidation process has bad step coverage so that the thickness of the HTO layer 245 on the trench 230B sidewall is much thinner than that on the trench 230B bottom.

Referring to FIG. 2d, after the HTO layer 245 formations, a portion of the HTO layer 245 located on the trench 230B sidewall is stripped.

Turning to FIG. 2e, a SiN layer 250 is then deposited on the HTO layer 245 through LPCVD and the thickness of the SiN layer 250 is about 100˜300 Å. Afterward, a photoresist layer is covered on the epi-layer 205 and filled into the trench 230B in the meanwhile. Then, a photoresist pattern 255, which is aimed at protect the HTO layer 245 in the trench 230B and exposed the SiN layer 250 on the surface of the epi-layer 205, is formed using a lithographic step.

After removing the exposed SiN layer 250, the HTO layer 245, remaining photoresist pattern 255 and the SiN layer 250 that is protected by the remaining photoresist pattern 255 are successively removed. Finally, the HTO layer 245 is remained in the trench 230B bottom as shown in FIG. 2f.

FIG. 2g illustrates a cross-sectional view. A polycrystalline silicon layer 260 is subsequently doped through an in-situ doped process on the surface of the epi-layer 205 and filled into the trench 230B. Referring to FIG. 2h, the doped polysilicon layer 260 and the intrinsic polysilicon layer 240, which are located under the doped polysilicon layer 260, are removed through an etching back process. A photoresist pattern 270 is then formed on the epi-layer 205 to define positions of source regions. Thereafter, an ion implant is carried out to implant n-type ions into the epi-layer 205 so as to form source regions 280, using the photoresist pattern 270 as a mask. Its result is shown in FIG. 2i.

Please refer to FIG. 2j, an inter-layer dielectrics layer is deposited on the mesa surface of the epi-layer 205 and the doped polysilicon layer 260 by CVD. The inter-layer dielectrics layer is composed of un-doped NSG 290 or BPSG 300 or NSG 290/BPSG 300 Plate-type Structure.

Referring to FIG. 2k, a patterning process by using a lithography and an etch process are subsequently done to define a source contact region (as shown in figure) and a gate contact position (located at the end of said trench, not shown in the figure). Before forming a metal layer, an ion implant is carried out by using aforementioned photoresist pattern as a mask to implant into the source contact region and the gate contact region as a pretreatment process so as to decrease the resistance of an ohmic contact between the inter-layer dielectrics layer and said later metal layer.

Still referring to FIG. 2k, a TiN layer 310 is forming on the inter-layer dielectrics layer pattern through a sputtering process so as to be a barrier between the inter-layer dielectrics layer 310 and the later metal layer, and even used for increasing the adhesion of the later metal layer. Next, the metal layer 320 is formed on the TiN layer 310 by sputtering. The connection between the source contact 330 and the trench gate contact (not shown in the figure) is defined through a lithographic and an etch step.

Before forming a drain metal layer, the foregoing layers formed over a rear surface of the substrate 200 are removed firstly. A metal layer 340 is then formed as a drain contact on the rear surface of the substrate 200 using a sputtering step. And the result of the present invention is shown in FIG. 2l. While the first embodiment of the invention has been illustrated and described above, it will be appreciated that various changes can be made therein. According to a second embodiment shown in FIG. 3a, it's shown in a cross-sectional view of the trench MOSFET. A semiconductor device of the second embodiment is similar to that of the first embodiment except that oxide nodes 410 is inserted on intersections between said vertical SiN layer 250 and said HTO layer 245 by oxidizing portions of exposed said first polysilicon layer 240. The oxide node 410 is aimed at break the continuity between the first polysilicon layer on the trench sidewall 240A and an the first polysilicon layer on the trench bottom 240B as shown in the figure and further prevent that impurities of the doped polysilicon layer are drove in the un-doped polysilicon layer by thermal diffusion during following process from losing the function of the oxide-un-doped poly-oxide dielectric layer, which is used for reducing the gate to drain capacitance. Then, please refer to the following illustration of completing the semiconductor device shown in FIG. 3a. Before FIG. 2d (not included), the steps are the same with the first embodiment.

Therefore, turning to FIG. 3b, a SiN layer 248 is deposited through a first LPCVD. The SiN layer 248 on the mesa surface of the epi-layer 205 and the trench 230B bottom is removed in order to expose the HTO layer 245 and the un-doped polysilicon layer 240, which is the boundary between the HTO layer 245 of the trench bottom and the SiN layer 248, through an anisotropic etch process. Then, an oxidation process is carried out on the exposed portion of the trench 230B bottom to break the continuity between the un-doped polysilicon layer on the trench sidewall 240A and the un-doped polysilicon layer on the trench bottom 240B so as to form the oxide node 410 as shown in FIG. 3c.

Referring to FIG. 3d, a SiN layer 250 is subsequently deposited through a second LPCVD and the thickness of the SiN layer 250 is about 100˜300 Å. The following process is the same with the process of the first embodiment after FIG. 2d (not included).

According to aforementioned embodiments, while the sizes of various devices in semiconductor processes have gotten smaller and smaller, the present invention is a benefit to reduce the gate to drain capacitance of the trench MOSFET and improve the switching speed cased by RC time delay.

As is understood by a person skilled in the art, the foregoing preferred embodiment of the present o invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1a to FIG. 1d are cross-sectional views of forming a trench power MOSFET in accordance with the prior art;

FIG. 2a is a cross-sectional view of forming a p-well regions in an epi-layer formed by selecting implant and defining an active region on the epi-layer by a lithographic and an etch step in accordance with the present invention;

FIG. 2b is a cross-sectional view of forming trenches in the epi-layer by selected etching in accordance with the present invention;

FIG. 2c is a cross-sectional view of forming a gate oxide layer, an intrinsic polysilicon layer and a HTO layer in accordance with the present invention;

FIG. 2d is a cross-sectional view of stripping the HTO layer of the trench sidewall in accordance with the present invention;

FIG. 2e is a cross-sectional view of forming a SiN layer and filling the trench with a photoresist pattern in accordance with the present invention;

FIG. 2f is a cross-sectional view of forming a HTO layer of the trench bottom in accordance with the present invention;

FIG. 2g is a cross-sectional view of forming a polysilicon layer on the surface of the epi-layer and filling the trench through an in-situ doping process in accordance with the present invention;

FIG. 2h is a cross-sectional view of removing the doped polysilicon layer and the intrinsic polysilicon layer on the opening of the trench and filling the trench with a photoresist pattern in accordance with the present invention;

FIG. 2i is a cross-sectional view of forming a source region using an ion implantation step in accordance with the present invention;

FIG. 2i is a cross-sectional view of forming an inter-layer dielectric layer on the surface of the epi-layer by CVD in accordance with the present invention;

FIG. 2k is a cross-sectional view of forming a source contact metal layer and a trench gate contact metal layer in accordance with the present invention;

FIG. 2l is a the cross-sectional views of forming the trench MOSFET in accordance with the present invention;

FIG. 3a is a the cross-sectional views of forming the trench MOSFET according to the second embodiment;

FIG. 3b is a the cross-sectional views of forming a SiN layer on the surface, the sidewall and the bottom oxide of the trench through a first LPCVD in accordance with the second embodiment;

FIG. 3c is a the cross-sectional views of forming an oxide node in accordance with the second embodiment; and

FIG. 3d is a the cross-sectional views of forming a SiN layer through the second LPCVD in accordance with the second embodiment.

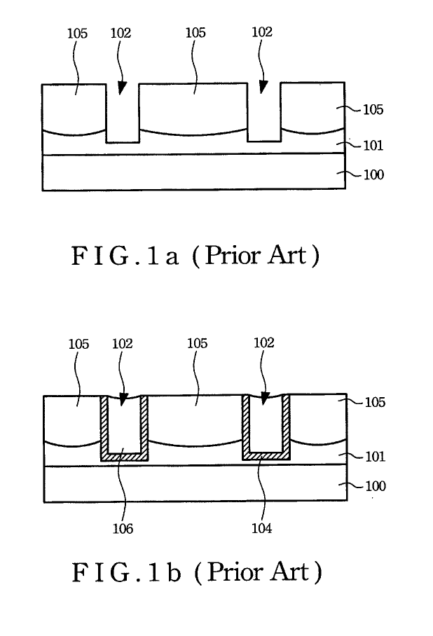

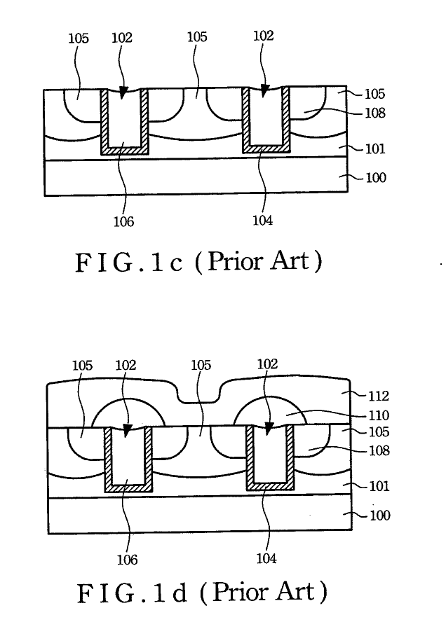

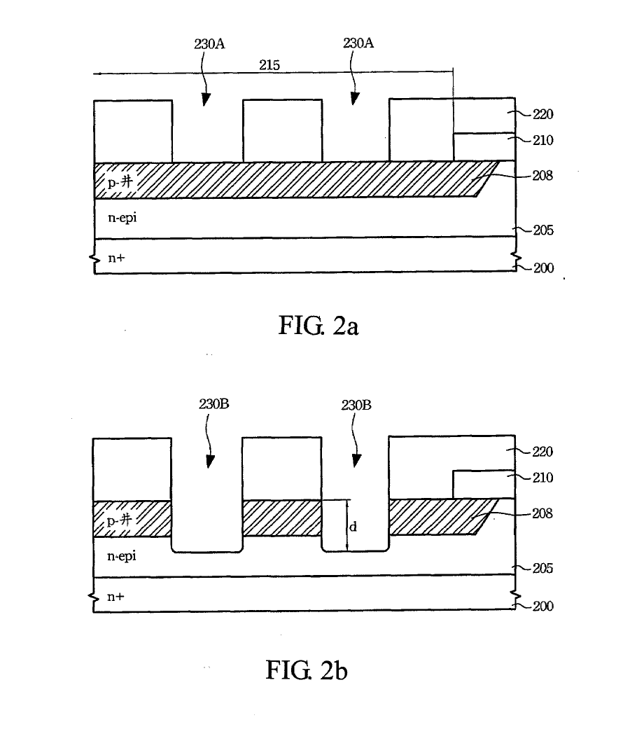

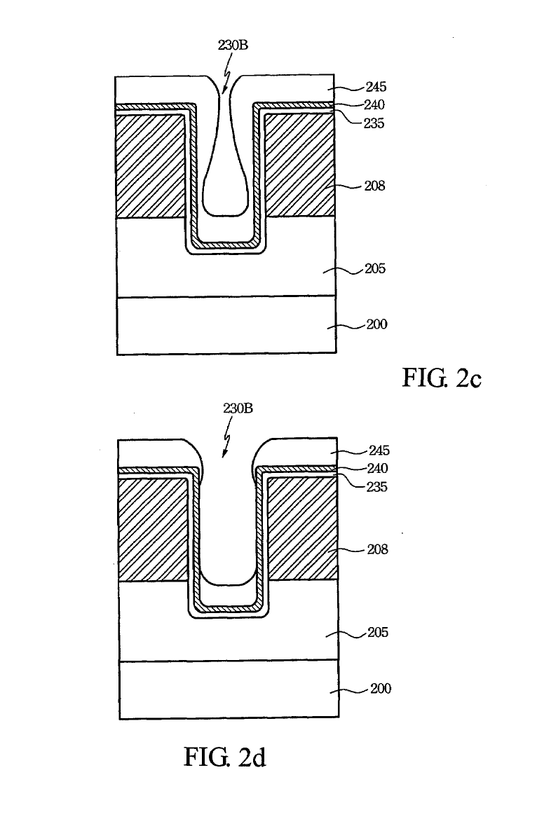

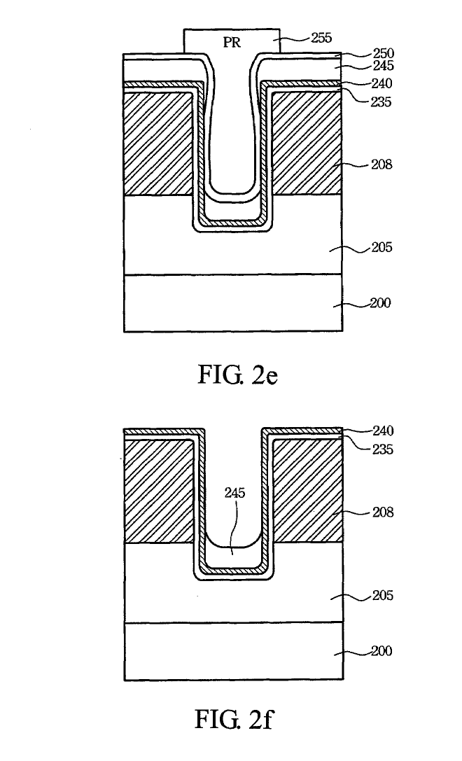

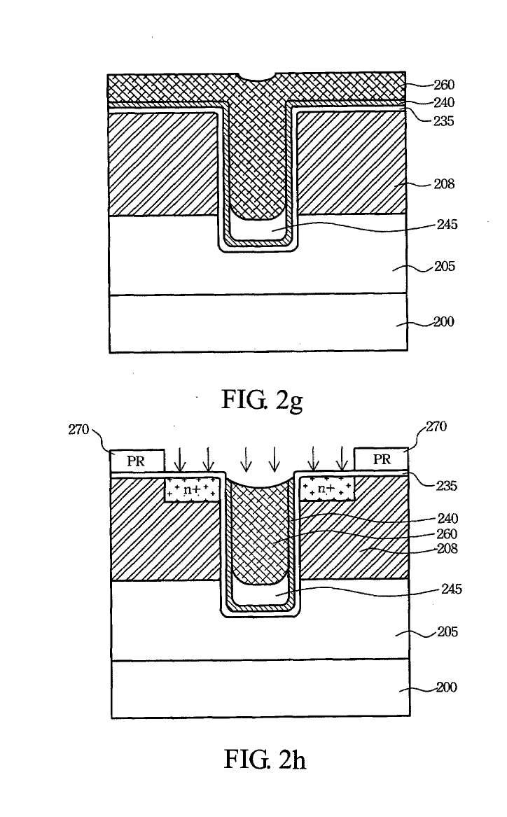

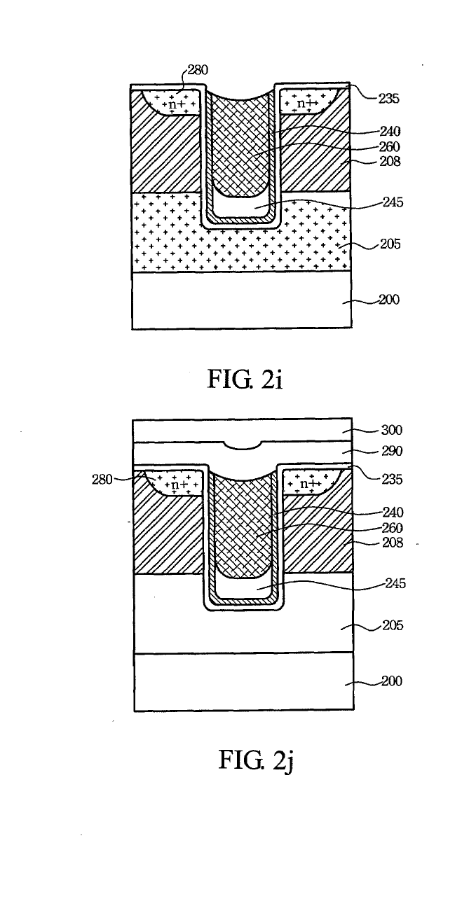

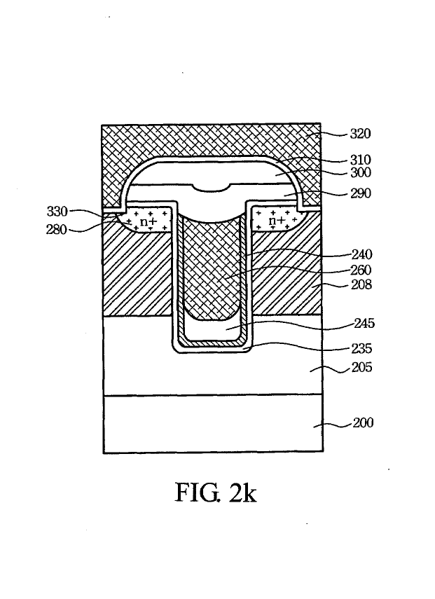

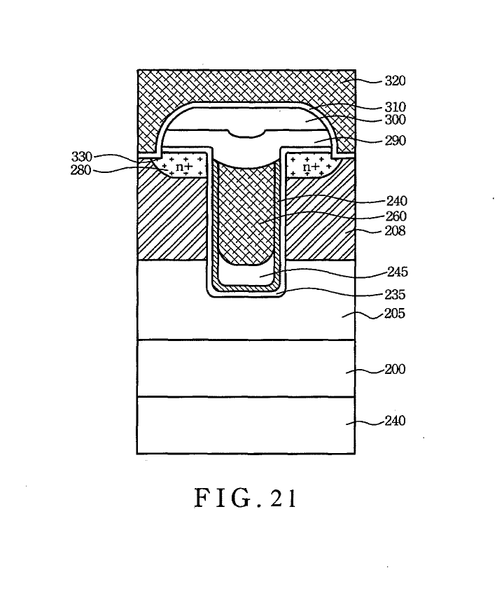

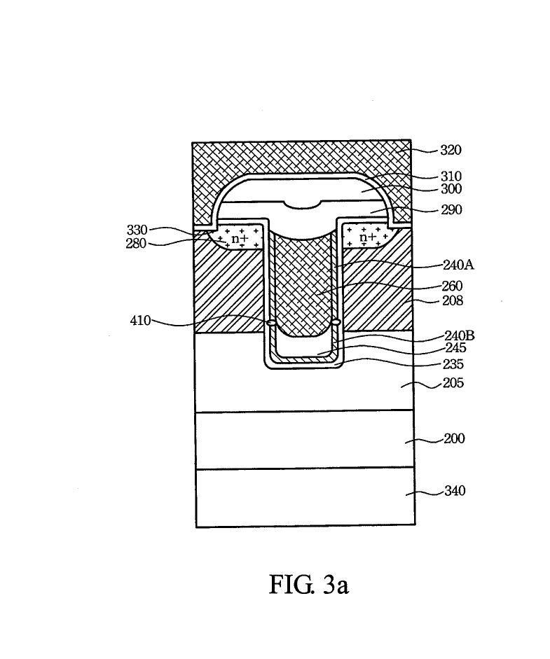

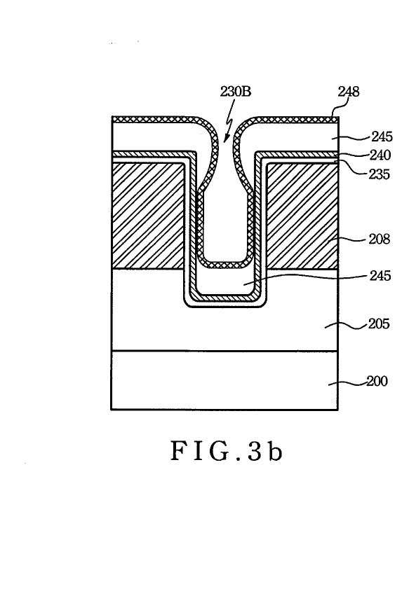

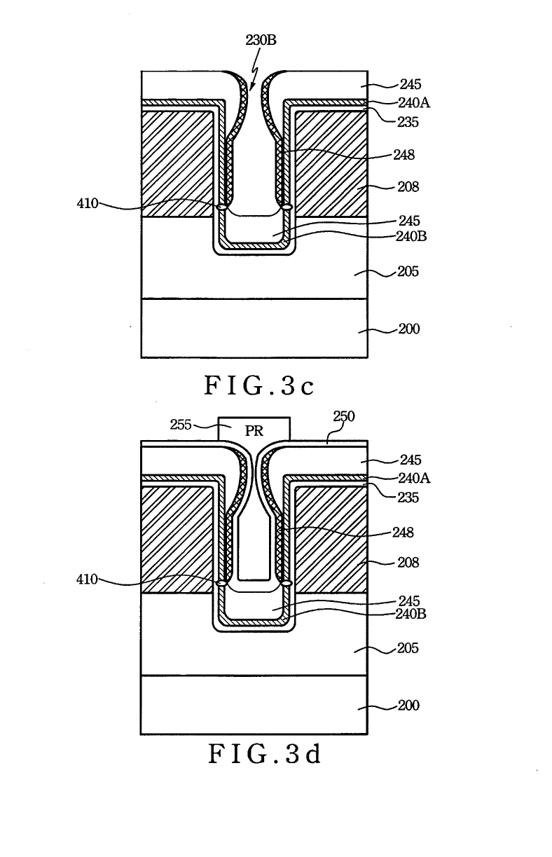

What is claimed is:

1. A method of forming trench MOSFET device, the method comprising the steps of:
providing an n-type heavily doped substrate having an n-type epi-layer formed thereon, and a p-well formed in said n-type epi-layer and extended to its surface;
forming a first oxide layer on said epi-layer through a thermal oxidation process;
patterning said first oxide layer to define an active region;
forming trenches in said epi-layer through a lithographic and an etch step;
performing said thermal oxidation process to form a gate oxide layer on bottoms and sidewalls of said trenches and a plurality of mesa surfaces therebetween;
forming an intrinsic first polysilicon layer on said gate oxide layer;
forming a high temperature oxide (HTO) layer on a portion of said first polysilicon layer on said trench bottoms;
performing an in-situ doped second polysilicon layer on said surface of said epi-layer and filling said trenches;
performing an etch back process to remove said second polysilicon, said HTO layer and said first polysilicon layer by using said gate oxide layer on said mesa surfaces as an etching stopping layer;
forming a first photoresist pattern having openings on entire surfaces to define positions of source regions;
performing a first ion implant through said gate oxide layer to implant n-type impurities into said epi-layer to form said source regions using said first photoresist pattern as a mask;
removing said first photoresist pattern;
forming an inter-layer dielectric layer over remained second polysilicon layer and said gate oxide layer over said mesa surfaces;
patterning said inter-layer dielectric layer to define positions of said source contacts and gate contacts;
forming a top metal layer to connect said source contacts and said trench gate contact regions through a metal sputtering and a patterning process; and
forming a metal layer as a drain electrode on a rear surface of said n-type heavily doped substrate.

2. The method of claim 1, wherein said step of forming the trenches comprise the steps of:
forming a second oxide layer on said epi-layer;
patterning said second oxide layer to form a hard mask pattern; and
performing an anisotropic etch process to etch said epi-layer and form said trenches using said hard mask as a mask.

3. The method of claim 1, wherein said step of forming said HTO layer on said trench bottoms comprise the steps of:
forming a HTO layer on portions of said first polysilicon layer through a thermal deposition step;
stripping portions of said HTO layer on said trench sidewalls;
forming a SiN layer on said HTO layer;
forming a photoresist pattern having a photo resist layer to fill said trenches;
performing an etching process to successively remove said SiN layer and said HTO layer by using said photo resist layer as a mask;
removing said photoresist pattern; and
removing said exposed SiN layer.

4. The method of claim 3, wherein before the step of forming a photoresist pattern and after the step of forming a SiN layer further comprises the steps of: and
performing an anisotropic etch process to remove said SiN layer on the mesa surface of said substrate and said trench bottoms;
forming oxide nodes on intersections between said vertical SiN layer and said HTO layer by oxidizing portions of exposed said first polysilicon layer;
forming a second SiN layer on entire aforementioned surfaces.

5. The method of claim 1, post the step of patterning said inter-layer dielectric layer to define said source contact region and said gate contact position further comprising a step of performing an ion implant to implant into said exposed source contact regions and gate contact as a pretreatment process before sputtering.

6. The method of claim 1 wherein the depth of said trench from its bottom to the surface of said second conductive layer is about 0.6 μm-5 μm, and the thickness of said intrinsic polysilicon layer is of about 300-800 Å, and said SiN layer is of about 100-300 Å.

7. A trench MOSFET structure, comprising:
a n-type heavily doped substrate having an n-type epi-layer formed thereon and having a p-well formed in said n-type epi-layer and extended to its surface;
a gate oxide layer conformally formed on a trench bottom, sidewall, and exposed to cover portions of said epi-layer;
a first polysilicon layer conformally formed on a portion of said gate oxide layer on the trench bottom and sidewall;
a high temperature oxide layer conformally formed on a portion of said first polysilicon layer on the trench bottom;
a second polysilicon layer filled into the trench bottom;
a source region formed in said p-well of the two sides of said trench;
a dielectric layer formed on said trench and covered partial surface of said source regions;
a source contact metal layer formed on said dielectric layer; and
a drain contact metal layer formed on a rear surface of said n-type heavily doped substrate.

8. The trench MOSFET structure of claim 7 wherein said HTO layer of said trench bottoms further comprising an oxide node located at the border between said HTO layer of said trench sidewalls, said HTO layer of said trench bottom and said SiN layer.

9. The trench MOSFET structure of claim 7 wherein said trench bottoms are lower than said epi-layer, and the depth of said trenches from their bottom to the surface of said epi-layer is about 0.6 μm-5 μm.

10. The trench MOSFET structure of claim 7 wherein the material of said dielectric layer is NSG or BPSG or NSG/BPSG.
